(19) United States
(12) Patent Application Publication
(10) Pub. No.: US 2023/0032080 A1
(43) Pub. Date: Feb. 2, 2023

(54) ASYMMETRIC LATERAL BIPOLAR TRANSISTOR AND METHOD

(71) Applicant: GLOBALFOUNDRIES U.S. Inc., Malta, NY (US)

(72) Inventors: Alexander M. Derrickson, Saratoga Springs, NY (US); Mankyu Yang, Fishkill, NY (US); Judson R. Holt, Ballston Lake, NY (US); Jagar Singh, Clifton Park, NY (US); Alexander L. Martin, Greenfield Center, NY (US); Richard F. Taylor, III, Campbell, CA (US)

(73) Assignee: GLOBALFOUNDRIES U.S. Inc., Malta, NY (US)

(21) Appl. No.: 17/388,284

(22) Filed: Jul. 29, 2021

(51) Int. Cl. H01L 29/735; H01L 29/417; H01L 29/08; H01L 29/66

(52) U.S. Cl. CPC H01L 29/735; H01L 29/0804; H01L 29/0821; H01L 29/6625; H01L 29/41708; H01L 29/66553

(57) ABSTRACT

Disclosed is a semiconductor structure that includes an asymmetric lateral bipolar junction transistor (BJT). The BJT includes an emitter, a base, a collector extension and a collector arranged side-by-side (i.e., laterally) across a semiconductor layer. The emitter, collector and collector extension have a first type conductivity with the collector extension having a lower conductivity level than either the emitter or the collector. The base has a second type conductivity that is different from the first type conductivity. With such a lateral configuration, the BJT can be easily integrated with CMOS devices on advanced SOI technology platforms. With such an asymmetric configuration and, particularly, given the inclusion of the collector extension but not an emitter extension, the BJT can achieve a relatively high collector-emitter breakdown voltage (V_{br-CEO}) without a significant risk of leakage currents at high voltages. Also disclosed are method embodiments for forming such a semiconductor structure.

### BACKGROUND

### Field of the Invention

The present invention relates to bipolar junction transistors (BJT) and, more particularly, to embodiments of semiconductor structure including a lateral BJT and embodiments of a method of forming the semiconductor structure.

### Description of Related Art

Advantages associated with manufacturing complementary metal oxide semiconductor (CMOS) designs using advanced silicon-on-insulator (SOI) processing technology platforms (e.g., a fully-depleted silicon-on-insulator (FDSOI) processing technology platform) include, for example, reduced power, reduced area consumption, reduced cost, high performance, multiple core threshold voltage (Vt) options, etc. CMOS designs manufactured on such SOI wafers are used in a variety of applications including, but not limited to, Internet-of-Things (IOT) devices, wearable devices, smartphone processors, automotive electronics, and radio frequency integrated circuits (RFICs) (including millimeter wave (mmWave) ICs). These same applications could benefit from the inclusion of bipolar junction transistors (BJTs) because BJTs tend to have more drive and are generally considered better suited for analog functions than field effect transistors (FETs). Typically, BJTs are formed as vertical devices (e.g., with an in-substrate collector, a base aligned above the collector, and an emitter aligned above the base). Unfortunately, integration of vertical BJTs and CMOS devices on advanced SOI technology platforms can be complex and expensive.

### SUMMARY

Generally, disclosed herein are embodiments of a semiconductor structure that includes a semiconductor layer. The semiconductor structure also includes an asymmetric lateral bipolar junction transistor (BJT) that has been formed using the semiconductor layer. Specifically, the BJT can include an emitter, a base, a collector extension (also referred to herein as a depleted collector region), and a collector arranged side-by-side (i.e., laterally) across the semiconductor layer. The emitter can at least include a first emitter portion in the semiconductor layer. The base can include a first base portion in the semiconductor layer positioned laterally adjacent to the first emitter portion. The base can further include a second base portion on the semiconductor layer above the first base portion. The second base portion can have opposing sidewalls and dielectric sidewall spacers positioned laterally adjacent to the opposing sidewalls. The collector extension can be in the semiconductor layer positioned laterally adjacent to the first base portion such that the first base portion is positioned laterally between and immediately adjacent to the first emitter portion and the collector extension. The collector can at least include a first collector portion in the semiconductor layer positioned laterally adjacent to the collector extension such that the collector extension is positioned laterally between and immediately adjacent to the first base portion and the first collector portion. The emitter, the collector, and the collector extension can have a first type conductivity with the collector extension having a lower conductivity level than the collector and the emitter. The base can have a second type conductivity that is different from the first type conductivity.

In some embodiments, the semiconductor structure can include a silicon layer and an asymmetric lateral bipolar junction transistor (BJT) that has been formed using the silicon layer. Specifically, the BJT can include an emitter, a base, a collector extension (also referred to herein as a depleted collector region), and a collector arranged side-by-side (i.e., laterally) across the silicon layer. The emitter can include a first emitter portion in the silicon layer and a second emitter portion on the silicon layer aligned above the first emitter portion. The base can include a first base portion in the silicon layer positioned laterally adjacent to the first emitter portion and a second base portion on the silicon layer aligned above the first base portion. The second base portion can have opposing sidewalls and dielectric sidewall spacers positioned laterally adjacent to the opposing sidewalls. The collector extension can be in the silicon layer positioned laterally adjacent to the first base portion such that the first base portion is positioned laterally between and immediately adjacent to the first emitter portion and the collector extension. The collector can include a first collector portion, which is in the silicon layer positioned laterally adjacent to the collector extension such that the collector extension is positioned laterally between and immediately adjacent to the first base portion and the first collector portion, and a second collector portion on the silicon layer aligned above the first collector portion. Given the inclusion of a collector extension but not an emitter extension, the second base portion can be separated from the second emitter portion by a first distance and can be separated from the second collector portion by a second distance that is greater than the first distance. In any case, the emitter, the collector, and the collector extension can have a first type conductivity with the collector extension having a lower conductivity level than the collector and the emitter. The base can have a second type conductivity that is different from the first type conductivity.

With such a lateral configuration, the BJT can be easily integrated with CMOS devices on advanced SOI technology platforms. Furthermore, with such an asymmetric configuration and, particularly, given the inclusion of the collector extension but not an emitter extension, the BJT can achieve a relatively high collector-emitter breakdown voltage (V_{br-CEO}) without a significant risk of leakage currents at high voltages. Thus, the BJT is suitable for use in power amplifiers or the like that require a relatively high V_{br-CEO}.

Also disclosed herein are method embodiments for forming the above-described semiconductor structure embodiments. Generally, the method embodiments can include accessing a semiconductor layer. The method embodiments can further include forming an asymmetric lateral bipolar junction transistor (BJT) using the semiconductor layer. The BJT can be formed so that it includes an emitter, a base, a collector extension (also referred to herein as a depleted collector region), and a collector arranged side-by-side (i.e., laterally) across the semiconductor layer. The emitter can be formed so that it at least includes a first emitter portion in the semiconductor layer. The base can be formed so that it includes a first base portion in the semiconductor layer positioned laterally adjacent to the first emitter portion and a second base portion on the semiconductor layer adjacent to the first base portion. The second base can further have opposing sidewalls with dielectric sidewall spacers positioned laterally adjacent to the opposing sidewalls. The collector extension can be formed in the semiconductor layer positioned laterally adjacent to the first base portion such that the first base portion is positioned laterally between and immediately adjacent to the first emitter portion and the collector extension. The collector can be formed so that it at least includes a first collector portion, which is in the semiconductor layer positioned laterally adjacent to the collector such that the collector extension is positioned laterally between and immediately adjacent to the first base portion and the first collector portion. In any case, the emitter, the collector, and the collector extension can be formed so as to have a first type conductivity with the collector extension having a lower conductivity level than the collector and the emitter. The base can be formed so as to a second type conductivity that is different from the first type conductivity.

### BRIEF DESCRIPTION OF THE SEVERAL VIEWS OF THE DRAWINGS

The present invention will be better understood from the following detailed description with reference to the drawings, which are not necessarily drawn to scale and in which:

FIG. 1 is a cross-section diagram illustrating an embodiment of a semiconductor structure that includes an asymmetric lateral bipolar junction transistor (BJT);

FIG. 2 is a flow diagram illustrating method embodiments for forming the semiconductor structure of FIG. 1; and

FIGS. 3-11 are cross-section diagrams illustrating partially-completed semiconductor structures formed according to the flow diagram of FIG. 2.

### DETAILED DESCRIPTION

As mentioned above, advantages associated with manufacturing complementary metal oxide semiconductor (CMOS) designs using advanced silicon-on-insulator (SOI) processing technology platforms (e.g., a fully-depleted silicon-on-insulator (FDSOI) processing technology platform) include, for example, reduced power, reduced area consumption, reduced cost, high performance, multiple core threshold voltage (Vt) options, etc. CMOS designs manufactured on such SOI wafers are used in a variety of applications including, but not limited to, Internet-of-Things (IOT) devices, wearable devices, smartphone processors, automotive electronics, and radio frequency integrated circuits (RFICs) (including millimeter wave (mmWave) ICs). These same applications could benefit from the inclusion of bipolar junction transistors (BJTs) because BJTs tend to have more drive and are generally considered better suited for analog functions than field effect transistors (FETs). Typically, BJTs are formed as vertical devices (e.g., with an in-substrate collector, a base aligned above the collector, and an emitter aligned above the base). Unfortunately, integration of vertical BJT and CMOS devices on advanced SOI technology platforms can be complex and expensive. To simplify such integration, symmetrical lateral BJTs have been developed where the base region is positioned laterally between essentially identical collector and emitter regions. However, the collector-emitter breakdown voltage (V_{br-CEO}) of such symmetrical lateral BJTs has been found to be relatively low. As a result, these symmetrical lateral BJTs are not suitable for use in power amplifiers or the like that require a relatively high V_{br-CEO}. One technique that can be employed to raise V_{br-CEO} is to increase the dopant concentration in the base region (Nb). However, increasing Nb can result in band-to-band tunneling (BTBT), thereby causing leakage currents at high voltages (e.g., when V_{br-CEO} is greater than or equal to the collector-base breakdown voltage (V_{br-CBO})).

In view of the foregoing, disclosed herein are embodiments of a semiconductor structure that includes an asymmetric lateral bipolar junction transistor (BJT). The BJT can include an emitter, a base, a collector extension (also referred to herein as a depleted collector region), and a collector arranged side-by-side (i.e., laterally) across a semiconductor layer. The emitter, collector and collector extension can have a first type conductivity with the collector extension having a lower conductivity level than either the emitter or the collector. The base can have a second type conductivity that is different from the first type conductivity. With such a lateral configuration, the BJT can be easily integrated with CMOS devices on advanced SOI technology platforms. Furthermore, with such an asymmetric configuration and, particularly, given the inclusion of the collector extension but not an emitter extension, the BJT can achieve a relatively high collector-emitter breakdown voltage (V_{br-CEO}) without a significant risk of leakage currents at high voltages. Thus, the BJT is suitable for use in power amplifiers or the like that require a relatively high V_{br-CEO}. Also disclosed herein are method embodiments for forming such a semiconductor structure.

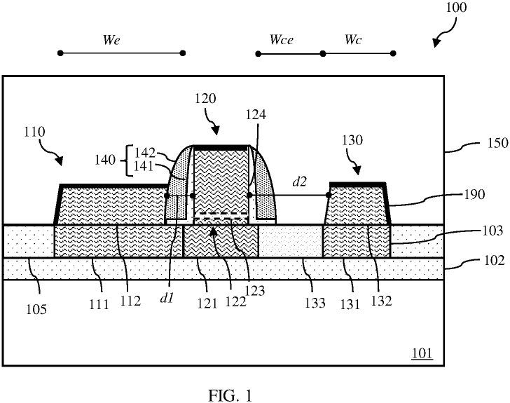

FIG. 1 is a cross-section diagram illustrating an embodiment of a semiconductor structure. This semiconductor structure can include a semiconductor layer 103. In some embodiments, the semiconductor layer 103 can be, for example, a semiconductor layer of a semiconductor-on-insulator structure, as illustrated. That is, the semiconductor structure can include a semiconductor substrate 101 (e.g., a silicon substrate), an insulator layer 102 (e.g., a silicon dioxide layer, referred to herein as a buried oxide (BOX) layer) on the semiconductor substrate 101, and a semiconductor layer 103 (e.g., a silicon layer or some other suitable semiconductor layer) on the insulator layer 102. Alternatively, the semiconductor layer could refer to a bulk semiconductor substrate (e.g., a bulk silicon substrate or some other suitable bulk semiconductor substrate) in its entirety (not shown).

The semiconductor structure can further include an asymmetric lateral bipolar junction transistor (BJT) 100 that has been formed using the semiconductor layer. For purposes of illustration, the BJT 100 is described in detail below and illustrated in the figures as being formed using the semiconductor layer 103 of a semiconductor-on-insulator structure. Thus, in some embodiments, the BJT 100 is electrically isolated from the semiconductor substrate 101 by an insulator layer 102. It should be understood that the figures are not intended to be limiting and that, alternatively, the BJT could be formed using the upper portion of a bulk semiconductor substrate and electrically isolated from the lower portion of the same bulk semiconductor substrate by, for example, a deep well implant.

Optionally, the semiconductor structure can further include isolation regions 105 (e.g., shallow trench isolation (STI) regions). The STI regions 105 can include, for example, trenches, which extend essentially vertically into the semiconductor layer from the top surface (e.g., down to the insulator layer 102), which define the BJT area within the semiconductor layer, and which are filled with one or more layers of isolation material (e.g., silicon dioxide, silicon nitride, etc.).

In any case, the BJT 100 can include an emitter 110; a base 120; a collector extension 133; and a collector 130 arranged side-by-side (i.e., laterally) across the semiconductor layer 103. The emitter 110, collector extension 133 (also referred to herein as a depleted collector region), and collector 130 can all have a first type conductivity with the collector extension 133 specifically having a lower conductivity level than the emitter 110 or collector 130. The base 120 can have a second type conductivity that is different from the first type conductivity. Thus, for example, in the case of an NPN-type BJT, the emitter 110, the collector extension 133, and the collector 130 can all have N-type conductivity with the collector extension 133 being an N- region, the emitter 110 being an N+ region, and with the collector 130 similarly being an N+ region. In the case of a PNP-type BJT, the emitter 110, the collector extension, 133 and the collector 130 can all have P-type conductivity with the collector extension 133 being a P- region, the emitter 110 being a P+ region, and with the collector 130 similarly being a P+ region.

More specifically, the emitter 110 can include a first emitter portion 111. The first emitter portion 111 can be a doped region within the semiconductor layer 103. The first emitter portion 111 can be doped with a sufficient concentration of a first dopant so as to have the first type conductivity at a relatively high conductivity level. The emitter 110 can also include a second emitter portion 112 that is immediately adjacent to the top surface of the semiconductor layer 103 and specifically aligned above the first emitter portion 111. The second emitter portion 112 can be an epitaxial semiconductor layer (e.g., an epitaxial silicon layer or some other suitable epitaxial layer) that is monocrystalline in structure and doped with the first dopant so as to also have the first type conductivity also at a relatively high conductivity level.

The base 120 can include a first base portion 121. The first base portion 121 can be another doped region within the semiconductor layer 103. The first base portion 121 can be doped with a sufficient concentration of a second dopant so as to have the second type conductivity. As discussed in detail below with regard to the method embodiments, one technique for forming the BJT can include a process step during which the semiconductor layer 103 is initially doped with a relatively low concentration of the first dopant and another process step during which the portion of the semiconductor layer associated with the base 120 is also doped with the second dopant such that, even with the presence of the first dopant, the resulting first base portion 121 has the second type conductivity. In any case, the first base portion 121 can be positioned laterally adjacent to the first emitter portion 111 within the semiconductor layer 103. The base 120 can also include a second base portion 122 that is immediately adjacent to the top surface of the semiconductor layer 103 and specifically aligned above the first base portion 121. The second base portion 122 can be an epitaxial semiconductor layer 124 (e.g., an epitaxial silicon layer or some other suitable epitaxial layer) that is monocrystalline in structure and doped with the second dopant so as to also have the second type conductivity at a relatively high conductivity level).

Optionally, as discussed in greater detail below with regard to the method embodiments, the second base portion 122 can also include an epitaxial semiconductor etch marker layer 123. This epitaxial semiconductor etch marker layer 123 can be below the epitaxial semiconductor layer 124 (i.e., such that it is stacked between and immediately adjacent to the top surface of the semiconductor layer 103 and the bottom surface of the epitaxial semiconductor layer 124). Alternatively, this epitaxial semiconductor etch marker layer 123 can be embedded within the epitaxial semiconductor layer 124 close to the top surface of the semiconductor layer 103, as illustrated. In any case, this epitaxial semiconductor etch marker layer 123 can be made of a different semiconductor material than the epitaxial semiconductor layer 124 and the semiconductor layer 103. For example, if the semiconductor layer 103 and the epitaxial semiconductor layer 124 are both silicon layers, then the epitaxial semiconductor etch marker layer 123 could be an epitaxial germanium layer, an epitaxial silicon germanium layer, an epitaxial silicon carbide layer or any other suitable epitaxial semiconductor layer that can function as an etch marker layer (also referred to herein as an etch stop layer) during processing, as discussed in greater detail below with regard to the method embodiments.

The collector extension 133 can be yet another doped region in the semiconductor layer 103. The collector extension 133 can be doped with the first dopant so as to have the first type conductivity but at a relatively low conductivity level. The collector extension 133 can be positioned laterally adjacent to the first base portion 121 such that, within the semiconductor layer 103, the first base portion 121 is positioned laterally between and immediately adjacent to the first emitter portion 111 and the collector extension 133.

The collector 130 can include a first collector portion 131. The first collector portion 131 can be yet another doped region within the semiconductor layer 103. The first collector portion 131 can be doped with a sufficient concentration of the first dopant so as to have the first type conductivity at a relatively high conductivity level and, particularly, at a conductivity level that is greater than that of the collector extension 133. The first collector portion 131 can be positioned laterally adjacent to the collector extension 133 such that, within the semiconductor layer 103, the collector extension 133 is positioned laterally between and immediately adjacent to the first base portion 121 and the first collector portion 131. The collector 130 can also include a second collector portion that is immediately adjacent to the top surface of the semiconductor layer 103 and specifically aligned above the first collector portion 131. The second collector portion 132 can be an epitaxial semiconductor layer (e.g., an epitaxial silicon layer or some other suitable epitaxial layer) that is monocrystalline in structure and doped with the first dopant so as to also have the first type conductivity also at a relatively high conductivity level.

In some embodiments, the width of the emitter 110 (We) (e.g., as measured from an adjacent STI 105 to the interface, within the semiconductor layer 103, between the first emitter portion 111 and the first base portion 121) can be greater than the width of the collector 130 (Wc) (e.g., as measured from an adjacent STI 105 to the interface, within the semiconductor layer 103, between the first collector portion 131 and the collector extension 133), as illustrated. In some embodiments, the width of the emitter 110 (We) (e.g., as measured from an adjacent STI 105 to the interface, within the semiconductor layer 103, between the first emitter portion 111 and the first base portion 121) can be approximately equal to the sum of the width of the collector 130 (Wc) (e.g., as measured from an adjacent STI 105 to the interface, within the semiconductor layer 103, between the first collector portion 131 and the collector extension 133) and the width of the collector extension 133 (Wce) (e.g., as measured from the interface, within the semiconductor layer 103, between the first collector portion 131 and the collector extension 133 to the interface, within the semiconductor layer 103 between the collector extension 133 and the first base portion 121), as illustrated. In some embodiments, Wce could be approximately equal to Wc, as illustrated. However, it should be understood that the figures are not intended to be limiting and that, alternatively, Wc could be different from Wce, Wc could be approximately equal to We, and/or Wce plus Wc could be greater than We.

In any case, given the asymmetric configuration and, more particularly, given the inclusion of the collector extension 133 within the semiconductor layer 103 but not an emitter extension, the second base portion 122 is separated from the second emitter portion 112 by a first distance (d1) (e.g., as measured from a first side and, particularly, the emitter side of the second base portion 122) and is separated from the second collector portion 132 by a second distance (d2) (e.g., as measured from a second side and, particularly, the collector side of the second base portion 122) that is greater than the first distance (d1).

The semiconductor structure can further include dielectric sidewall spacers 140, which are positioned laterally adjacent to the opposing sidewalls of the second base portion 122 (i.e., on the first side and the second side, respectively). These dielectric sidewall spacers 140 can include an emitter-side sidewall spacer, which is positioned laterally between and immediately adjacent to the second emitter portion 112 of the emitter 110 and the first side of the second base portion 122. As illustrated, this emitter-side sidewall spacer can be aligned above the interface between the first emitter portion 111 and the first base portion 121 within the semiconductor layer 103 (i.e., aligned above the emitter-base interface within the semiconductor layer). These dielectric sidewall spacers 140 can also include a collector-side sidewall spacer, which is positioned laterally immediately adjacent to the second side of the second base portion 122 and which is physically separated from the second collector portion 132 by a space. As illustrated, this collector-side sidewall spacer can be aligned above the interface between the first base portion 121 and the collector extension 133 within the semiconductor layer 103 (i.e., aligned above the base-collector extension interface within the semiconductor layer 103) such that at least some portion of the collector extension 133 extends laterally beyond the collector-side sidewall spacer to the first collector portion 131.

In some embodiments, the dielectric sidewall spacers 140 can be multi-layered sidewall spacers. For example, each sidewall spacer 140 could include a relatively thin first spacer layer 141 with a horizontal portion on the top surface of the semiconductor layer 103 and a vertical portion extending upward from the horizontal portion along the sidewall of the second base portion 122 (i.e., each sidewall spacer could include an essentially L-shaped first spacer layer). The first spacer layer 141 could be made of a first spacer material (e.g., silicon dioxide or some other suitable first spacer material). Each sidewall spacer 140 could also include a second spacer layer 142 on the horizontal portion of the first spacer layer 141. This second spacer layer 142 could be made of a second spacer material that is different from the first spacer material (e.g., silicon nitride or some other suitable second spacer material). However, it should be understood that the figures are not intended to be limiting and that, alternatively, the sidewalls spacers 140 could be single layer sidewall spacers (e.g., nitride spacers only) or could have more than two layers.

The semiconductor structure can further include metal silicide layers 190, which are immediately adjacent to at least the top surfaces of the second emitter portion 112, the second base portion 122, and the second collector portion 132. The metal silicide layers 190 can be, for example, layers of cobalt silicide (CoSi), nickel silicide (NiSi), tungsten silicide (WSi), titanium silicide (TiSi), or any other suitable metal silicide material.

The semiconductor structure can further include one or more layers of dielectric material 150 covering the second emitter portion 112, the second base portion 122, the sidewall spacers 140 adjacent to the second base portion 122 (including the emitter-side sidewall spacer and the collector-side sidewall spacer), the collector extension 133, the second collector portion 132, and the adjacent STIs 105. The one or more layers of dielectric material can include a blanket layer of interlayer dielectric (ILD) material (e.g., a blanket silicon dioxide layer or some other blanket ILD material layer). Optionally, the one or more layers of dielectric material can include one or more additional layers of dielectric material between the BJT and the blanket layer of ILD material. The additional layer(s) could include conformal dielectric layers (e.g., a conformal nitride etch stop layer, not shown). In any case, the dielectric material 150 can fill the space between the collector-side sidewall spacer and the second collector portion 132 and can be immediately adjacent to the top surface of the semiconductor layer 103 above the collector extension 133. Thus, while the second emitter portion 112 is physically separated from the second base portion 122 by only a sidewall spacer (i.e., the emitter-side sidewall spacer), the second collector portion 132 is physically separated from the second base portion 122 by a sidewall spacer (i.e., the collector-side sidewall spacer) and also a section of the dielectric material 150.

Additional features of the semiconductor structure can include, but are not limited to: CMOS devices formed using the semiconductor layer 103 in other areas of the structure; middle of the line (MOL) contacts that extend through the dielectric material 150 to the metal silicide layers 190 on the top surfaces of the emitter, base, and collector; back end of the line BEOL metal levels, etc.

As mentioned above, in some embodiments, the asymmetrical lateral BJT could be an NPN-type BJT. In such an NPN-type BJT structure, the semiconductor layer 103 could be a silicon layer. The second emitter portion 112 and the second collector portion 132 can be doped with an N-type dopant (e.g., phosphorous or some other suitable N-type dopant) at a concentration of approximately 4x10²⁰ atoms/cm³ such that they have a relatively high N-type conductivity level. The first emitter portion 111 and the first collector portion 131 can be doped with the same N-type dopant at a concentration that may be somewhat less than 4x10²⁰ atoms/cm³, but that is still relatively high (e.g., at or above 1x10¹⁹ atoms/cm³) such that they also have a relatively high N-type conductivity level. The collector extension 133 can also be doped with the same N-type dopant but at a concentration that is significantly less than 4x10²⁰ atoms/cm³. For example, the collector extension 133 can have a first dopant concentration of approximately 1x10¹⁸ atoms/cm³ and, thereby a relatively low N-type conductivity level. The second base portion 122 can be doped with a P-type dopant (e.g., boron or some other suitable P-type dopant) at a concentration of approximately 1x10²⁰ atoms/cm³ such that it has a relatively high P-type conductivity level. The first base portion 121 can be doped with the same N-type and P-type dopants discussed above but the relative concentrations of the two different dopants can be such the first base portion 121 has a relatively low P-type conductivity level.

With such a lateral configuration, the BJT 100 can be easily integrated with CMOS devices on advanced SOI technology platforms. Furthermore, with such an asymmetric configuration and, particularly, given the inclusion of the collector extension 133 but not an emitter extension, the BJT 100 can achieve a relatively high collector-emitter breakdown voltage (V_{br-CEO}) without a significant risk of leakage currents at high voltages. Thus, the BJT is suitable for use in power amplifiers or the like that require a relatively high V_{br-CEO}.

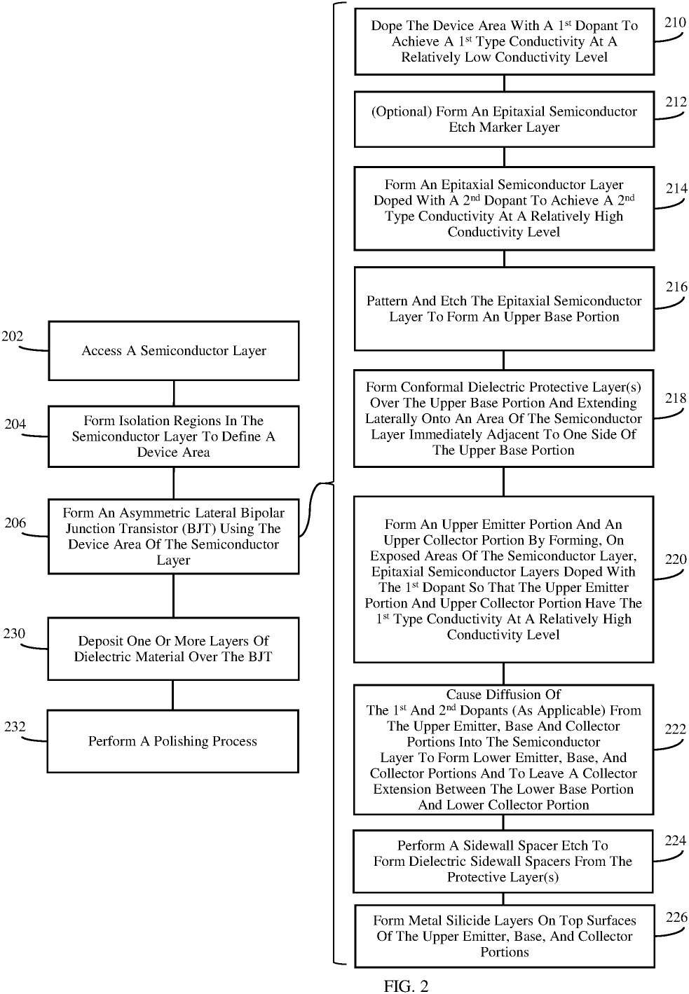

Referring to the flow diagram of FIG. 2, also disclosed herein are method embodiments for forming the above-described semiconductor structure.

The method embodiments can include accessing a semiconductor layer 103 (see process step 202 and FIG. 3). As illustrated in FIG. 3, the semiconductor layer 103 can be, for example, a semiconductor layer of a semiconductor-on-insulator structure, as illustrated. That is, the semiconductor structure can include a semiconductor substrate 101 (e.g., a silicon substrate), an insulator layer 102 (e.g., a silicon dioxide layer, referred to herein as a buried oxide (BOX) layer) on the semiconductor substrate 101, and a semiconductor layer 103 (e.g., a silicon layer or some other suitable semiconductor layer) on the insulator layer 102. Alternatively, the semiconductor layer could refer to a bulk semiconductor substrate (e.g., a bulk silicon substrate or some other suitable bulk semiconductor substrate) in its entirety (not shown). In any case, the semiconductor layer can be accessed (i.e., formed or otherwise acquired) and used to perform the process steps described below.

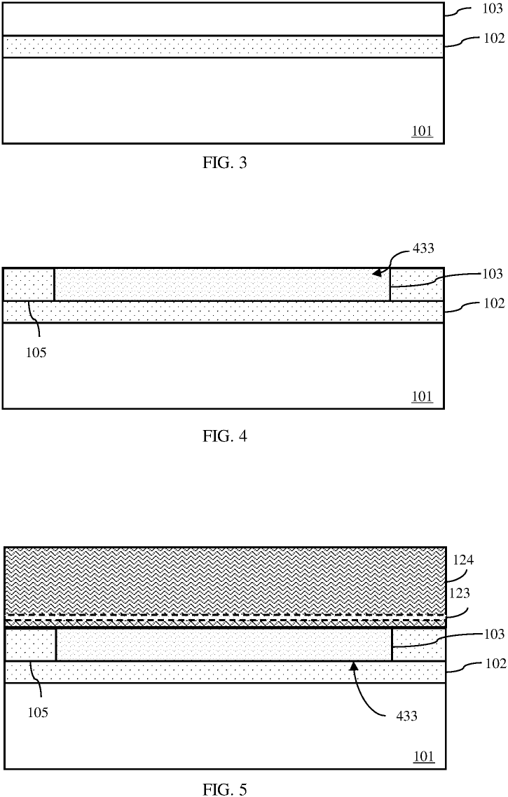

The method embodiments can include forming isolation regions 105 (e.g., shallow trench isolation (STI) regions) (see process step 204 and FIG. 4). Specifically, at process step 204, trenches for STI regions can be formed (e.g., lithographically patterned and etched using conventional STI processing techniques) such that they extend essentially vertically into the semiconductor layer from the top surface (e.g., down to the insulator layer 102) and such that they define a device area within the semiconductor layer. The trenches can further be filled with one or more layers of isolation material (e.g., silicon dioxide, silicon nitride, etc.).

The method embodiments can further include forming an asymmetric lateral bipolar junction transistor (BJT) using the semiconductor layer 103 (see process step 206). The asymmetrical lateral BJT formed at process step 206 can be, for example, the asymmetrical lateral BJT 100 described above and illustrated in FIG. 1. That is, the BJT 100 can be formed so that it includes an emitter 110, a base 120, a collector extension 133 (also referred to herein as a depleted collector region), and a collector 130 arranged side-by-side (i.e., laterally) across the semiconductor layer 103. The emitter 110 can be formed such that it includes a first emitter portion 111 in the semiconductor layer 103 and a second emitter portion 112 on the semiconductor layer 103 aligned above the first emitter portion 111. The base 120 can be formed such that it includes a first base portion 121 in the semiconductor layer 103 positioned laterally adjacent to the first emitter portion 111 and a second base portion 122 on the semiconductor layer aligned above the first base portion 121. The collector extension 133 can be formed in the semiconductor layer 103 positioned laterally adjacent to the first base portion 121 such that the first base portion 121 is positioned laterally between and immediately adjacent to the first emitter portion 111 and the collector extension 133. The collector 130 can be formed so that it includes a first collector portion 131, which is in the semiconductor layer 103 positioned laterally adjacent to the collector extension 133 such that the collector extension 133 is positioned laterally between and immediately adjacent to the first base portion 121 and the first collector portion 131, and a second collector portion 132 on the semiconductor layer 103 aligned above the first collector portion 132. Given the formation of a collector extension 133 but not an emitter extension, the second base portion 122 will be separated from the second emitter portion 112 by a first distance (d1) and separated from the second collector portion 132 by a second distance (d2) that is greater than the first distance (d1) In any case, the emitter, the collector, and the collector extension can all be formed so as to have a first type conductivity with the collector extension 133 having a lower conductivity level than the collector 130 and the emitter 110. The base 120 can be formed so as to have a second type conductivity that is different from the first type conductivity with the first base portion 121 having a relatively low conductivity level as compared to the second base portion 122.

In an exemplary process flow, the BJT 100 can be formed at process step 206 as follows. The semiconductor layer 203 and, more particularly, the device area defined by the STI regions 105 can be doped with a first dopant (e.g., using a dopant implantation process) (see process step 210 and the doped device area 433 in FIG. 4). The first dopant can be selected in order to achieve a first type conductivity (see the detailed discussion below regarding exemplary dopants that can be used to achieve different type conductivities depending upon the type of semiconductor material at issue). Furthermore, the specifications used for doping the device area at process step 210 can be sufficient to achieve the first type conductivity at a first conductivity level and, particularly, at a relatively low first-type conductivity level.

Subsequently, at least one epitaxial semiconductor layer can be formed on the semiconductor layer 103 (process steps 212-214 and epitaxial semiconductor layers 123-124 in FIG. 5). Specifically, an epitaxial semiconductor layer 124 that is monocrystalline in structure (e.g., an epitaxial silicon layer or some other suitable epitaxial layer) can be formed on the semiconductor layer 103 and in situ doped with the second dopant so as to also have the second type conductivity at a relatively high conductivity level. Optionally, before or during epitaxial deposition of the semiconductor layer 124, an epitaxial semiconductor etch marker layer 123 can also be epitaxially deposited such that it is either below the epitaxial semiconductor layer 124 (i.e., such that it is stacked between and immediately adjacent to the top surface of the semiconductor layer 103 and the bottom surface of the epitaxial semiconductor layer 124) or embedded within the epitaxial semiconductor layer 124 close to the semiconductor layer 103, as illustrated. In any case, this epitaxial semiconductor etch marker layer 123 can be made of a different semiconductor material than the epitaxial semiconductor layer 124 and the semiconductor layer 103. For example, if the semiconductor layer 103 and the epitaxial semiconductor layer 124 are both silicon layers, then the epitaxial semiconductor etch marker layer 123 could be an epitaxial germanium layer, an epitaxial silicon germanium layer, an epitaxial silicon carbide layer or any other suitable epitaxial semiconductor layer that can function as an etch marker layer (also referred to herein as an etch stop layer) during processing, as discussed in greater detail below at process step 216.

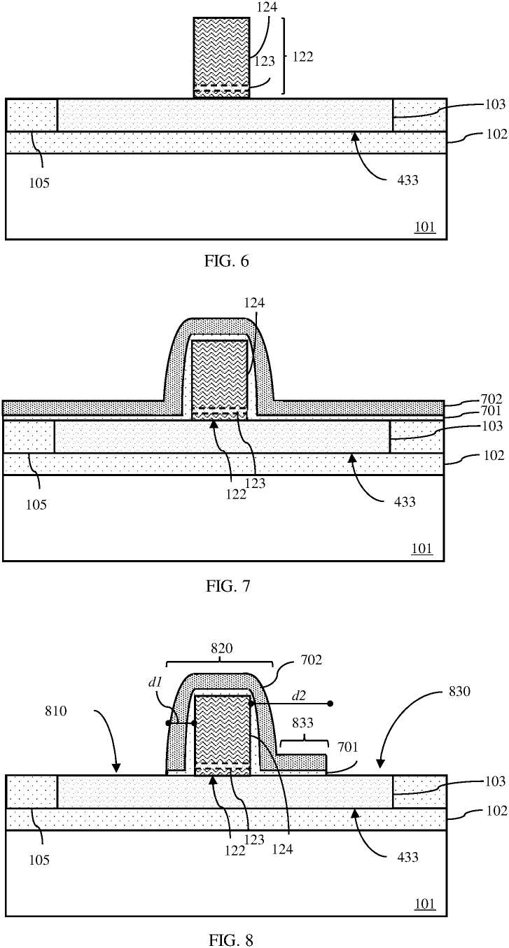

The second base portion 122 of the base 120 (also referred to herein as an upper base portion) can be formed from the epitaxial semiconductor layer 124 and, if present, the epitaxial semiconductor etch marker layer 123 (see process step 216 and FIG. 6). Specifically, a mask can be formed over the designated base area (e.g., using conventional lithographic patterning). Then, at least one selective anisotropic etch process can be performed in order to pattern the second base portion 122 from the epitaxial semiconductor layer 124 and, if present, the epitaxial semiconductor etch marker layer 123. For example, an anisotropic etch process can be time so that it is stopped in time to avoid over-etching the semiconductor layer 103 and, particularly, to avoid etching completely through the semiconductor layer 103. Alternatively, instead of simply relying on a timed anisotropic etch process, a first anisotropic etch process can be performed to selectively etch through the epitaxial semiconductor layer 124, stopping on the epitaxial semiconductor etch marker layer 123. Next, a second anisotropic etch process can be performed to selectively etch through the epitaxial semiconductor etch marker layer 123 stopping on the semiconductor layer 103. Those skilled in the art will recognize, while the second anisotropic etch process may be selective to the epitaxial semiconductor etch marker layer 123, some etching of the semiconductor material below may occur due to the different materials and the ability to achieve true etch selectivity. However, generally, the etch rate into the semiconductor layer will be significantly slower than the etch rate through the epitaxial semiconductor etch stop layer so that the second anisotropic etch process can be stopped before the etched openings extend completely through the semiconductor layer. In any case, the resulting second base portion 122 will have opposing sidewalls and, particularly, a first side (also referred to herein as an emitter side) and a second side (also referred to herein as a collector side) opposite the first side.

One or more conformal protective layers can then be formed over the partially completed structure (see process step 218 and FIG. 7). These protective layer(s) can be made of dielectric materials and can include, for example, a relatively thin conformal silicon dioxide layer 701 and a conformal silicon nitride layer 702 on the silicon dioxide layer. Various conformal thin film deposition techniques are well known in the art and, thus, the details of such techniques have been omitted from this specification in order to allow the readers to focus on the salient aspects of the disclosed embodiments. The protective layer(s) can then be patterned (e.g., using conventional lithographic patterning and anisotropic etch techniques) so that a first remaining portion 820 of the stack of protective layer(s) 701-702 covers the first side, top surface, and second side of the second base portion 122 and so that a second remaining portion 833 of the stack of protective layer(s) 701-702 (which is continuous with the first remaining portion 820) extends laterally onto an area of the semiconductor layer 103 immediately adjacent to the second side (see FIG. 8). As a result of this patterning process, a first area 810 of the semiconductor layer 103, which is a first distance (d1) from the first side of the second base portion 122, is exposed and a second area 830 of the semiconductor layer 103, which is separated from the second side of the second base portion 122 by a second distance (d2) that is greater than the first distance (d1), is also exposed.

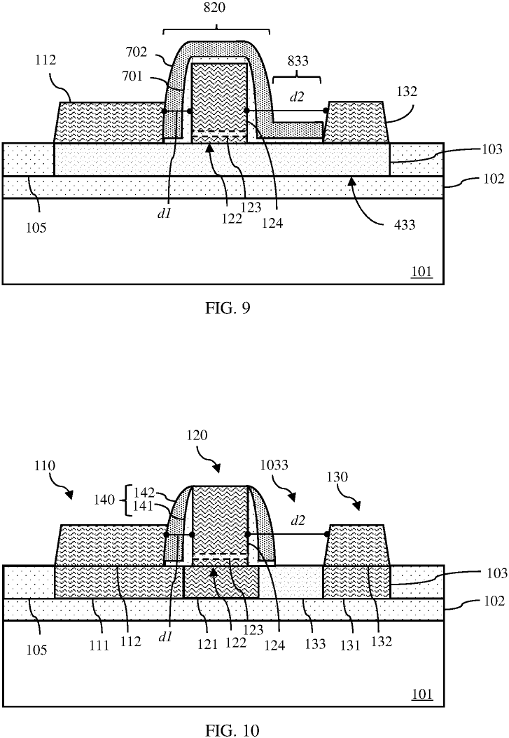

Then, epitaxial semiconductor layers that are monocrystalline in structure (e.g., epitaxial silicon layers) can be formed on the exposed first area 810 and the exposed second area 830 of the semiconductor layer 103 in order to form the second emitter portion 112 (also referred to herein as the upper emitter portion) and a second collector portion 132 (also referred to herein as the upper collector portion), respectively (see process step 220 and FIG. 9). The epitaxial semiconductor layers can be in situ doped with the first dopant so as to have the first type conductivity at least at a second conductivity level that is greater than the first conductivity level (which was achieved in the device area through the dopant implantation process used at process step 210 discussed above).

It should be noted that at least one anneal process can be performed in the process flow after formation of the second emitter portion 112 and the second collector portion 132 in order to activate the dopants as well as to cause dopants from the second emitter portion 112, the second base portion 122, and the second collector portion 132 to diffuse into corresponding portions of the semiconductor layer 103 below, thereby forming the first emitter portion 111 (also referred to herein as the lower emitter portion), the first base portion 121 (also referred to as the lower base portion), and the first collector portion 131 (also referred to herein as the lower collector portion (see process step 222 and FIG. 10). Anneal processes that can be employed to activate dopants and to cause the desired dopant diffusion can be global (e.g., rapid thermal anneal) and/or local/directed (e.g., laser anneal). Such anneal processes are well known in the art and, thus, the details thereof have been omitted from this specification in order to allow the reader to focus on the salient aspects of the disclosed embodiments. In any case, following the dopant diffusion at process step 222, the collector extension 133 (i.e., the depleted collector region) will be that portion of the semiconductor layer 103, which is positioned laterally between and immediately adjacent to the first base portion 121 and the first collector portion 131 and which still has the first type conductivity at the first conductivity level (i.e., at the relatively low conductivity level).

Additionally, a sidewall spacer etch can be performed (see process step 224 and FIG. 10). Specifically, one or more anisotropic etch processes can be performed in order to remove horizontal portions of the remaining stack of conformal protective layer(s) 701-702, leaving behind vertical portions and, particularly, dielectric sidewall spacers 140 on the first side and the second side of the second base portion. The resulting dielectric sidewall spacers 140 can include an emitter-side sidewall spacer, which is aligned above an emitter-base interface within the semiconductor layer 103 and which is positioned laterally between and immediately adjacent to the second emitter portion 112 and the second base portion 122; and a collector-side sidewall spacer, which is aligned above a base-collector extension interface within the semiconductor layer and which is positioned laterally immediately adjacent to the second base portion 122 and physically separated from the second collector portion 132 by a space 1033. The sidewall spacer etch at process step 224 also exposed the top surface of the second base portion 122 and the top surface of the semiconductor layer 103 (at the collector extension 133) within the space 1033. Sidewall spacer etch techniques are well known in the art and, thus, the details thereof have been omitted form this specification in order to allow the reader to focus on the salient aspects of the disclosed embodiments.

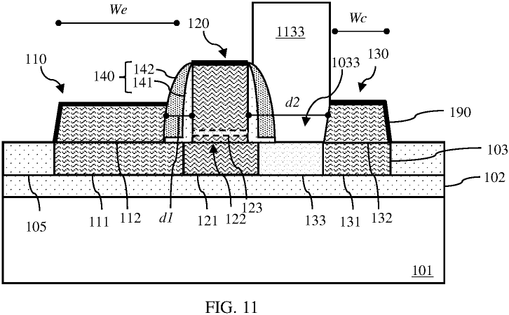

An additional protective layer 1133 (also referred to herein as a silicide block layer) can be formed (e.g., lithographically patterned and etched) so that it covers the exposed top surface of the semiconductor layer 103 in the space 1033 between the collector-side sidewall spacer and the second collector portion 132. Then, metal silicide layers 190 can be formed on exposed semiconductor surfaces and, particularly, on the top surfaces of the second emitter portion 112, the second base portion 122, and the second collector portion 132 (see process step 226 and FIG. 11). The metal silicide layers 190 can be, for example, layers of cobalt silicide (CoSi), nickel silicide (NiSi), tungsten silicide (WSi), titanium silicide (TiSi), or any other suitable metal silicide material. Such metal silicide layers 190 can be formed, for example, using a conventional self-aligned process. Following formation of the metal silicide layers 190, the additional protective layer 1133 can be selectively removed.

The method embodiments can further include formation of one or more layers of dielectric material 150 so as to cover the partially completed structure and, particularly, the second emitter portion 112, the second base portion 122, the dielectric sidewall spacers 140 adjacent to the second base portion 122 (including the emitter-side sidewall spacer and the collector-side sidewall spacer), the collector extension 133, the second collector portion 132, and the adjacent STIs 105 (see process step 230 and FIG. 1). For example, a blanket layer of interlayer dielectric (ILD) material (e.g., a blanket silicon dioxide layer or some other blanket ILD material layer) can be deposited over the partially completed structure. Optionally, prior to deposition of a blanket layer of ILD material, one or more additional layer(s) including, but not limited to one or more conformal dielectric layers (e.g., a conformal nitride etch stop layer, not shown) can be deposited over the partially completed structure. Techniques for blanket and conformal deposition of dielectric materials are well known in the art and, thus, the details thereof have been omitted from this specification in order to allow the reader to focus on the salient aspects of the disclosed embodiments. In any case, during deposition at process step 230, the dielectric material 150 can fill the space 1033 between the collector-side sidewall spacer and the second collector portion 132 such that it is immediately adjacent to the top surface of the semiconductor layer 103 above the collector extension 133. Thus, in the resulting structure, while the second emitter portion 112 is physically separated from the second base portion 122 by only a sidewall spacer 140 (i.e., the emitter-side sidewall spacer), the second collector portion 132 is physically separated from the second base portion 122 by a sidewall spacer 140 (i.e., the collector-side sidewall spacer) and also a section of the dielectric material 150. A polishing process (e.g., a conventional chemical mechanical polishing (CMP) process) can then be performed so that the dielectric material 150 has a top surface that is essentially parallel to the bottom surface of the substrate (see process step 232).

Additional processing can include, but is not limited to, integrating the above-described process steps with the formation of at least one CMOS device also using another area of the semiconductor layer 103; the formation of middle of the line (MOL) contacts that extend through the dielectric material 150 to the metal silicide layers 190 on the top surfaces of the emitter, base, and collector; the formation of back end of the line BEOL metal levels; etc.

It should be understood that in the method and structures described above, a semiconductor material refers to a material whose conducting properties can be altered by doping with an impurity. Exemplary semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on.

Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should be understood that the terminology used herein is for the purpose of describing the disclosed structures and methods and is not intended to be limiting. For example, as used herein, the singular forms "a", "an" and "the" are intended to include the plural forms as well, unless the context clearly indicates otherwise. Additionally, as used herein, the terms "comprises" "comprising", "includes" and/or "including" specify the presence of stated features, integers, steps, operations, elements, and/or components, but do not preclude the presence or addition of one or more other features, integers, steps, operations, elements, components, and/or groups thereof. Furthermore, as used herein, terms such as "right", "left", "vertical", "horizontal", "top", "bottom", "upper", "lower", "under", "below", "underlying", "over", "overlying", "parallel", "perpendicular", etc., are intended to describe relative locations as they are oriented and illustrated in the drawings (unless otherwise indicated) and terms such as "touching", "in direct contact", "abutting", "directly adjacent to", "immediately adjacent to", etc., are intended to indicate that at least one element physically contacts another element (without other elements separating the described elements). The term "laterally" is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a semiconductor layer;
a transistor comprising:
an emitter comprising: a first emitter portion in the semiconductor layer;
a collector comprising: a first collector portion in the semiconductor layer;
a collector extension in the semiconductor layer; and
a base comprising:
a first base portion in the semiconductor layer, wherein the first base portion is positioned laterally between the first emitter portion and the collector extension, and wherein the collector extension is positioned laterally between the first base portion and the first collector portion; and
a second base portion on the semiconductor layer adjacent to the first base portion and having opposing sidewalls; and
dielectric sidewall spacers positioned laterally adjacent to the opposing sidewalls.

2. The structure of claim 1,
wherein the emitter, the collector, and the collector extension have a first type conductivity,
wherein the base has a second type conductivity that is different from the first type conductivity, and
wherein the collector extension has a lower conductivity level than the collector.

3. The structure of claim 1,
wherein the emitter further comprises a second emitter portion on the semiconductor layer adjacent to the first emitter portion,
wherein the collector further comprises a second collector portion on the semiconductor layer adjacent to the first collector portion, and
wherein the sidewall spacers comprise:
an emitter-side sidewall spacer aligned above an emitter-base interface in the semiconductor layer and further positioned laterally between and immediately adjacent to the second emitter portion and the second base portion; and
a collector-side sidewall spacer aligned above a base-collector extension interface in the semiconductor layer and positioned laterally immediately adjacent to the second base portion and physically separated from the second collector portion by a space.

4. The structure of claim 3, further comprising at least one layer of dielectric material over the second emitter portion, the emitter-side sidewall spacer, the second base portion, the collector-side sidewall spacer, and the second collector portion, wherein the dielectric material fills the space between the collector-side sidewall spacer and the second collector portion and is immediately adjacent to a top surface of the semiconductor layer above the collector extension.

5. The structure of claim 3, wherein the second emitter portion, the second collector portion and the second base portion comprise epitaxial semiconductor layers.

6. The structure of claim 3,
wherein the second base portion comprises: an epitaxial semiconductor etch marker layer; and an epitaxial semiconductor layer on the epitaxial semiconductor etch marker layer, and
wherein the epitaxial semiconductor etch marker layer and the epitaxial semiconductor layer comprise different semiconductor materials.

7. The structure of claim 3, further comprising silicide layers on the second emitter portion, the second base portion, and the second collector portion.

8. A structure comprising:
a silicon layer;
a transistor comprising:
an emitter with a first type conductivity, wherein the emitter comprises:
a first emitter portion in the silicon layer; and
a second emitter portion on the silicon layer adjacent to the first emitter portion;
a collector with the first type conductivity, wherein the collector comprises:
a first collector portion in the silicon layer; and
a second collector portion on the silicon layer adjacent to the first collector portion;
a collector extension in the silicon layer, wherein the collector extension has the first type conductivity at a lower conductivity level than the collector; and
a base with a second type conductivity that is different from the first type conductivity, wherein the base comprises:
a first base portion in the silicon layer, wherein the first base portion is positioned laterally between the first emitter portion and the collector extension and wherein the collector extension is positioned laterally between the first base portion and the first collector portion; and
a second base portion on the silicon layer adjacent to the first base portion and having opposing sidewalls; and
dielectric sidewall spacers positioned laterally adjacent to the opposing sidewalls.

9. The structure of claim 8, wherein the transistor comprises any of the following:
an NPN-type bipolar junction transistor where the first type conductivity comprises N-type conductivity and the second type conductivity comprises P-type conductivity; and
a PNP-type bipolar junction transistor where the first type conductivity comprises P-type conductivity and the second type conductivity comprises N-type conductivity.

10. The structure of claim 8,
wherein the sidewall spacers comprise:
an emitter-side sidewall spacer aligned above an emitter-base interface in the silicon layer and positioned laterally between and immediately adjacent to the second emitter portion and the second base portion; and
a collector-side sidewall spacer aligned above a base-collector extension interface in the silicon layer and positioned laterally immediately adjacent to the second base portion and physically separated from the second collector portion by a space, and
wherein the second base portion is separated from the second emitter portion by a first distance and is separated from the second collector portion by a second distance that is greater than the first distance.

11. The structure of claim 10, further comprising at least one layer of dielectric material over the second emitter portion, the emitter-side sidewall spacer, the second base portion, the collector-side sidewall spacer, and the second collector portion, wherein the dielectric material fills the space between the collector-side sidewall spacer and the second collector portion and is immediately adjacent to a top surface of the silicon layer above the collector extension.

12. The structure of claim 8, wherein the second emitter portion, the second collector portion and the second base portion comprise epitaxial silicon layers.

13. The structure of claim 8, wherein the second base portion comprises: an epitaxial silicon germanium layer; and an epitaxial silicon layer on the epitaxial silicon germanium layer.

14. The structure of claim 8, further comprising silicide layers on the second emitter portion, the second base portion, and the second collector portion.

15. A method comprising:
accessing a semiconductor layer; and
forming a transistor using the semiconductor layer, wherein the transistor comprises:
an emitter comprising: a first emitter portion in the semiconductor layer;
a collector comprising: a first collector portion in the semiconductor layer;
a collector extension in the semiconductor layer; and
a base comprising:
a first base portion in the semiconductor layer, wherein the first base portion is positioned laterally between the first emitter portion and the collector extension, and wherein the collector extension is positioned laterally between the first base portion and the first collector portion; and
a second base portion on the semiconductor layer adjacent to the first base portion and having opposing sidewalls with dielectric sidewall spacers positioned laterally adjacent to the opposing sidewalls.

16. The method of claim 15, wherein the forming of the transistor comprises forming the transistor such that the emitter, the collector, and the collector extension have a first type conductivity, such that the base has a second type conductivity that is different from the first type conductivity, and such that the collector extension has a lower conductivity level than the collector.

17. The method of claim 15, wherein the forming of the transistor comprises:
doping the semiconductor layer so that the semiconductor layer has a first type conductivity at a first conductivity level;
forming an epitaxial semiconductor layer on the semiconductor layer, wherein the epitaxial semiconductor layer is doped so as to have a second type conductivity that is different from the first type conductivity;
forming a second base portion from the epitaxial semiconductor layer, wherein the second base portion has a first side and a second side opposite the first side;
forming at least one protective layer that covers the first side, top surface, and second side of the second base portion and that further extends laterally onto the semiconductor layer adjacent to the second side such that a first exposed area of the semiconductor layer is a first distance from the first side of the second base portion and such that a second exposed area of the semiconductor layer is separated from the second side of the second base portion by a second distance that is greater than the first distance;
forming epitaxial semiconductor layers on the first exposed area and the second exposed area to form a second emitter portion and a second collector portion, respectively, wherein the epitaxial semiconductor layers are doped so as to have the first type conductivity at a second conductivity level that is greater than the first conductivity level; and
exposing the top surface of the second base portion and forming, from the at least one protective layer, the sidewall spacers on the first side and the second side of the second base portion, wherein the sidewall spacers comprise an emitter-side sidewall spacer aligned above an emitter-base interface in the semiconductor layer and positioned laterally between and immediately adjacent to the second emitter portion and the second base portion; and a collector-side sidewall spacer aligned above a base-collector extension interface in the semiconductor layer and positioned laterally immediately adjacent to the second base portion and physically separated from the second collector portion by a space.

18. The method of claim 17, further comprising:
forming an additional protective layer over the semiconductor layer in the space between the collector-side sidewall spacer and the second collector portion;
forming silicide layers on the second emitter portion, the second base portion, and the second collector portion; and,
removing the additional protective layer.

19. The method of claim 17, further comprising:
causing dopants from the second emitter portion, the second base portion, and the second collector portion to diffuse into corresponding portions of the semiconductor layer below to form the first emitter portion, the first base portion, and the first collector portion, wherein the collector extension comprises a remaining portion of the semiconductor layer having the first type conductivity at the first conductivity level between the first base portion and the first collector portion; and
forming a least one layer of dielectric material over the second emitter portion, the emitter-side sidewall spacer, the second base portion, the collector-side sidewall spacer and the second collector portion, wherein the dielectric material fills the space between the collector-side sidewall spacer and the second collector portion and is immediately adjacent to a top surface of the semiconductor layer above the collector extension.

20. The method of claim 17, further comprising: forming an epitaxial semiconductor etch marker layer,
wherein the epitaxial semiconductor layer is formed on the epitaxial semiconductor etch marker layer,
wherein the epitaxial semiconductor layer and the epitaxial semiconductor etch marker layer comprise different semiconductor materials, and
wherein the forming of the second base portion comprises:
forming a mask on the epitaxial semiconductor layer;
performing a first selective anisotropic etch process to etch through the epitaxial semiconductor layer; and
performing a second selective anisotropic etch process to etch through the epitaxial semiconductor etch marker layer to complete formation of the second base portion, wherein the epitaxial semiconductor etch marker layer minimizes over-etching of the semiconductor layer.
